(19) United States
(12) Patent Application Publication
(10) Pub. No.: US 2004/0244673 A1
(43) Pub. Date: Dec. 9, 2004

(54) Microporous crystals and methods of making thereof

(76) Inventors: Matthew Z. Yates, Penfield, NY (US); Jen-Chieh Lin, Rochester, NY (US)

Correspondence Address: BLANK ROME LLP, 600 NEW HAMPSHIRE AVENUE, N.W., WASHINGTON, DC, 20037, US

(21) Appl. No.: 10/767,270

(22) Filed: Jan. 30, 2004

Related U.S. Application Data
(60) Provisional application No. 60/443,885, filed on Jan. 31, 2003.

(51) Int. Cl. C30B 1/00

(52) U.S. Cl. 117/2

(57) ABSTRACT

Novel microporous crystal morphologies are produced by combining a polar solute, a silicon or phosphorous source, and a structure directing agent. A premixed mixture of at least one surfactants and a hydrophobic solvent is added to the previously mixed three species and shaken to for a reverse microemulsion. The microemulsion is stirred overnight, at about room temperature and then iced for five to ten minutes. A metal source is added and vigorously shaken for about two minutes. The mixture is then aged for about two hours at about room temperature. After which, a mineralizer is added and the resultant mixture aged for about two hours at about room temperature. The mixture is then heated to about 100-220° C. The final novel product is then isolated.

### FIELD OF THE INVENTION

The present invention relates to microporous crystals. In particular, the present invention relates to novel zeotype framework microporous crystal species and methods of making thereof via reverse microemulsions in a hydrothermal synthesis process.

### BACKGROUND OF THE INVENTION

The continued growth of nanotechnology is inherently dependent on the development of new materials and new synthetic methodologies to control morphology on the nano-scale. As many systems, such as quantum dots, zeotypes, molecular magnets, and related areas, rely on complex host-guest interactions during synthesis, there is a need to better understand how these interactions guide the ultimate outcome of the synthesis.

The utility of nanoporous and mesoporous materials having porosity on the order of molecular dimensions and above as adsorbants for gas and liquid separations, catalysts, ion-exchange materials, and biomimetic materials is apparent and continues to proliferate rapidly. It has been estimated that refining efficiencies gained by processes based upon nanoporous catalysts save the United States approximately 200 million barrels of crude oil imports per year. New nanoporous materials are finding their way into new chemical processes as the petrochemical industry responds to increasing foreign competition and environmental regulation. New membrane-based techniques for gas separations, reactive separations, and membrane chemical reactors, and energy storage devices require new materials having porosity on the order of molecular dimensions. Longer range potential applications of nanoporous materials include molecular electronic and electro-optic devices. Discovering new, three-dimensional nanoporous inorganic networks is of key importance to these developing technologies. This requires developing a scientific understanding of the mechanisms of formation of open-framework inorganic compounds and in the understanding of the subtle interactions of the inorganic-organic host-guest complexes involved in the formation of the nanoporous crystals. A second crucial factor for the development of nano-scale devices is control over the crystallite morphology of these materials, particularly control over the orientation of the pore systems with respect to the external environment. Current research in zeotypes synthesis that is ongoing around the world is directed at the development and extension of suitable uses for porous materials.

Microporous crystals with pore sizes near molecular dimensions, such as zeolites (or zeotypes in general wherein the standard silicon is replaced with other equivalent metals) and molecular sieves (microporous metal oxide crystals in general), are widely used in shape-selective catalysis and separations, and are being developed for applications in membranes, sensors, and optics. (Advanced Zeolite Science and Applications (Ed.: J. C. Jansen), Elsevier, New York, 1994; and Davis, Ind. Eng. Chem. Res. 1991, 30:1675-1683). Because many emerging applications of microporous materials require precise control of crystal size and orientation (A. Kuperman et al., Nature1993, 365:239-242; and Feng et al., Science1994, 265:1839-1841), there is significant interest in developing new strategies to control crystal structure and morphology. Reverse microemulsions have been used to control the size and shape of some inorganic materials by confining the reaction within surfactant assemblies (Pileni, Langmuir1997, 13:3266-32761; and Li et al., Nature1999, 402:393-395). Microporous zincophosphates have also been crystallized at room temperature from reactants enclosed in reverse microemulsions (Dutta et al., Nature1995, 374:44-46; and Singh et al., Langmuir2000, 16:4148-4153). Zeolites and molecular sieves usually require hydrothermal synthesis conditions (T>100° C.), at which microemulsion formation is difficult to achieve.

The framework structures of zeolites or zeotypes in general with either silicon or suitable non-silicon equivalents) are complicated networks of interconnected Si—O rings and/or cages, with substitutions of heteroatoms (Al, B, Fe, Ga, Ti, and/or the like) onto Si sites or non-silicon equivalent sites. Of the approximately 104 crystallographically and chemically reasonable three dimensional networks of interconnected tetrahedral vertices predicted by graph theory, only 121 have been synthesized or found in nature, with a few more being synthesized each year. To prepare open-framework zeotypes an organic cation guest molecule (usually referred to as a “structure-directing agent” or SDA) is employed. The SDA directs the formation of molecular-scale inorganic-organic precursors that lead to the nucleation, growth, and crystallization of open-framework materials. The SDA is incorporated into the crystalline matrix, filling the void volumes of channels and cages, and balancing charge of the framework. The SDA is usually removed after crystallization by combustion or pyrolysis, as the SDA is very tightly confined within the surrounding structure. Most of the discoveries of open-framework topologies over the last six to eight years are the result of an increased understanding of the role of the SDA has in pre-organizing the inorganic building blocks and stabilizing the open-framework structure once formed.

The foregoing information reflects the state of the art of which the applicant is aware and is tendered with the view toward discharging applicant's acknowledged duty of candor in disclosing information which may be pertinent in the examination of this application. It is respectfully submitted, however, that none of the disclosed information teaches, suggests, implies, or renders obvious, singly or when considered in combination, applicant's claimed invention.

### SUMMARY OF THE INVENTION

The present invention presents a novel and very useful approach in increasing the rate of discovery of open-framework, nanoporous materials. The present invention relates to novel ideas in manipulating the ways in which the synthesis is conducted to step away from the conventional approaches being followed by the zeolite synthesis community. The present approach controls the reaction volume and medium during the initial growth stages to modulate structure and morphology to produce new framework topologies.

An object of the present invention is to provide a reverse microemulsions hydrothermal synthesis method for producing zeotype compounds.

Another object of the present invention is to furnish a hydrothermal synthesis for producing zeotypes having novel crystalline structures.

A further object of the present invention is to supply a reverse microemulsion hydrothermal synthesis method for producing novel AlPO₄-5 and Silicalite-1 compounds.

Still another object of the present invention is to disclose zeotype compounds having novel crystalline structures.

Yet a further object of the present invention is to describe AlPO₄-5 and Silicalite-1 compounds having novel crystalline structures.

Yet still a further object of the present Invention is to disclose AlPO₄-5 and Silicalite-1 compounds having novel crystalline structures that are produced by a reverse microemulsion hydrothermal synthesis method.

Disclosed is a method of generating novel zeotype framework microporous crystal species via reverse microemulsions under hydrothermal synthesis conditions. The subject method comprises the steps of mixing a hydrophilic solute, a silicon or phosphorous source, and a structure directing agent together; adding at least one surfactant and a hydrophobic solvent; and shaking to disperse the surfactants. The resultant reverse microemulsion is stirred for a first period of time at a first temperature. A metal source is then added to the stirred reverse microemulsion, either with or without prior cooling of the reverse microemulsion, and shaken vigorously for a second period of time and then allowed to age for a third period of time at a second temperature. A mineralizer is then added and the entire mixture is allowed to age for a fourth period of time and a third temperature. The total mixture is heated for a fifth period of time at a fourth temperature. The generated crystals are then isolated as the product.

More specifically, the present method, for a novel exemplary AlPO₄-5 species, comprises mixing water, phosphoric acid, and triethylamine together. Cetyl pyridinium chloride, n-butanol, and toluene are then added and shaken for approximately a minute to disperse the cosurfactants. The resultant reverse microemulsion is stirred overnight at about room temperature. Aluminum triisopropoxide is then added to the stirred reverse microemulsion, either with or without an approximately five to ten minute ice cooling of the reverse microemulsion, and shaken vigorously for about two minutes and then allowed to age for approximately two hours at room temperature. Hydrofluoric acid is then added and the entire mixture allowed to age for about two hours at room temperature. The total mixture is then heated, by conventional or microwave heating, to about 180° C. for an appropriate period of time, depending on the heating technique. The generated crystals are then isolated, washed, and dried as the product. An equivalent procedure is utilized to produce a novel form of Silicalite-1, as described below.

The subject invention has led to a better understanding of how zeolites and related compounds nucleate and grow. Understanding nucleation processes helps in developing new nanoporous materials having novel catalytic and separation capabilities. In particular, control over the morphology of the crystal growth through the use of reverse microemulsions is particularly challenging because the hydrothermal synthesis requires elevated temperatures and high concentrations of ions. Such control can be extended to the morphology of a wide range of complex materials including molecular magnets and nonlinear optic materials. In the area of zeolites, morphology control has direct application in the development of zeolite based membranes for separations that are currently plagued with lack of control over crystal orientation, formation of grain boundaries, and imperfections leading to inconsistent results.

Other objects, advantages, and novel features of the present invention will become apparent from the detailed description that follows, when considered in conjunction with the associated drawings.

### BRIEF DESCRIPTION OF THE DRAWINGS

The invention will be more fully understood by reference to the following drawings which are for illustrative purposes only:

FIG. 1A is a scanning electron micrographs of AlPO₄-5 synthesized in an autoclave at 180° C. for six hours showing AlPO₄-5 from microemulsion-based synthesis (bar equals 10 microns).

FIG. 1B is a scanning electron micrographs of AlPO₄-5 synthesized in an autoclave at 180° C. for six hours showing a close-up of fiber ends of AlPO₄-5 from microemulsion-based synthesis (bar equals 1 μm).

FIG. 1C is a scanning electron micrographs showing AlPO₄-5 from a traditional synthesis using an autoclave for heating (bar equals 10 μm).

FIG. 2A is a scanning electron micrographs of AlPO₄-5 synthesized by microwave heating at 180° C. for 17 minutes showing a) AlPO₄-5 from a microemulsion based synthesis (bar equals 1 μm).

FIG. 2B is a scanning electron micrographs of AlPO₄-5 from traditional synthesis using microwave heating (bar equals 10 μm).

FIG. 3A is a scanning electron micrographs of Silicalite-1 from the present synthesis scheme (bar equals 10 μm).

FIG. 3B is a scanning electron micrographs of Silicalite-1 from a traditional synthesis scheme (bar equals 10 μm).

FIG. 4 shows phase diagrams with the surfactant CPC and cosurfactant butanol in the ratio of 2 to 1 by weight. The region enclosed in black line is the one with double the standard molar ratio of structure directing agent (1.2: 1.0 of triethylamine:phosphoric acid). The dash-line region represents standard molar is ratio of triethylamine in the aqueous phase (0.6:1.0 of triethylamine:phosphoric acid). A-D are compositions chosen for hydrothermal synthesis with double the molar ratio of triethylamine. A′-C′ are compositions chosen for hydrothermal synthesis with the standard molar ratio of triethylamine.

FIGS. 5A-E show products from conventional heating (6 hrs at 180° C.) with double the standard amount of triethylamine. FIGS. 5A to 5D correspond to microemulsion compositions A to D, respectively, from FIG. 4. FIG. 5E is the control experiment without the microemulsion. The scale bars are 20 μm for A, B, and D; and 200 μm for C and E.

FIGS. 6A-E show X-ray diffraction patterns for products shown in FIGS. 5A to 5E, respectively.

FIGS. 7A-E show products from microwave heating (17 min at 180° C.) with double the standard amount of triethylamine. FIGS. 7A to 7D correspond to microemulsion compositions A to D, respectively, from FIG. 4. FIG. 7E is the control experiment without the microemulsion. The scale bars are A-10 μm, B2 μm, C-20 μm, D-2 μm, and E-20 μm.

FIGS. 8A-B show products from conventional heating (6 hrs at 180° C.) with standard triethylamine concentration. FIG. 8A is from a microemulsion with composition C′ of FIG. 4. FIG. 8B is the control experiment without the microemulsion. The scale bars are 200 μm.

FIGS. 9A-B show products from microwave heating (17 min at 180° C.) with standard triethylamine concentration. FIG. 9A is from a microemulsion with composition A′ of FIG. 4. FIG. 9B is the control experiment without the microemulsion. The scale bars are A-2 μm and B-20 μm.

FIG. 10 shows AlPO₄-5 fibers crystallized by microwave heating (17 min at 180° C.) with double the standard amount of triethylamine from a microemulsion with the weight ratio of CPC to butanol of 3 to 1. The scale bar is 2 μm.

FIG. 11 is a flow diagram illustrating a general synthesis method summary for the present invention.

FIG. 12 is a flow diagram illustrating a novel AlPO₄-5 synthesis method of the present invention.

### DETAILED DESCRIPTION OF THE PREFERRED EMBODIMENT

The present invention is concerned with certain classes of nanoporous materials that are prepared under hydrothermal synthesis conditions, such as zeolites (framework silicates consisting of interlocking tetrahedrons of SiO₄ and AlO₄) and their non-silicate analogs such as, but not limited to, aluminophosphates, where phosphate, for example, assumes the role of the silicate (collectively known as zeolite-types or zeotypes). Zeotypes are crystalline open framework materials having porosity on the order of molecular dimensions. These nanoporous materials have found tremendous technological utility as shape-selective catalysts, adsorbents, and ion exchangers. Scientifically, there is a keen interest in the mechanism of the nucleation and growth of these wonderfully complex structures and in the nature of the guest-host interactions that direct the formation of these complicated frameworks. The subject invention provides new approaches to influence the nucleation and growth of zeotypes grown under hydrothermal conditions. The subject techniques permit manipulations, in well-controlled fashion, of the chemical and physical environment in which these syntheses are performed.

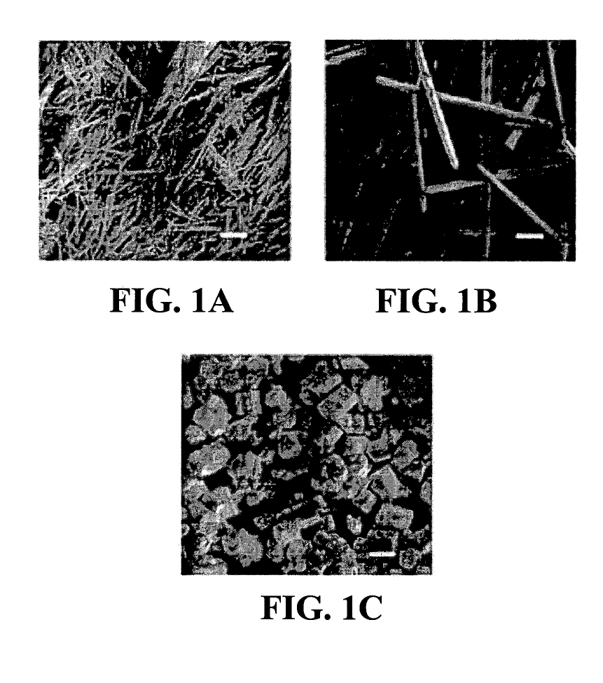

Referring to the drawings (FIGS. 1-11), for illustrative purposes, the present invention is disclosed for synthesizing complex metal oxide species, microporous metal oxide crystals, at hydrothermal conditions using microemulsions. More specifically, reverse microemulsions are utilized to synthesize high aspect ratio zeotype microporous crystals at the nanoscale. The zeotype microporous crystals are made in reverse microemulsions under hydrothermal conditions. It is believed that prior to the subject invention, microemulsion synthesis above 80° C. was unknown. The synthesis in reverse microemulsions results in zeotype microporous crystals that have aspect ratios up to 100 or more. The pores of the zeotype microporous crystal are aligned along the axis so that it may be possible to make zeotype membranes from such fibers. Aspect ratios for crystal species are also important for magnetic properties, optical materials to generate polarized light, and physical properties of composites. The subject synthesis method opens up a whole new area by making it possible to synthesize a much broader range of materials in microemulsions to control the product's morphology.

Reverse microemulsion is one mechanism to control features on the nanoscale by limiting the growth of crystals or acting as a reaction volume template to control aspect ratios. The control over complex systems, such as zeotypes is a challenge, especially when hydrothermal synthesis at temperatures usually >100° C. are required and the number of interacting components is large. Microemulsions result from the interaction of a surfactant with water-oil mixture. Traditional microemulsions have the water (hydrophilic/polar material) as the solvent and the oil (hydrophobic/non-polar material) as the solute, wherein the surfactant separates the two phases. In reverse microemulsions, as is the case with the subject invention, the solvent phase is the non-polar material and the solute phase is the polar water, still separated by the surfactant. Microemulsions and reverse microemulsions differ from traditional micelles in that traditional micelles are produced from amphipathic species and water and no separate surfactant(s) is required for solubilization; however, traditional micelle structures may be the basis for similar reactions or equivalent to those disclosed below for the subject microemulsion situation and are therefore considered within the disclosed bounds of this disclosure.

For example, an illustrative microemulsion forming system can be generated with a cationic SDA and appropriate mineralizer (OH⁻, pH of about 13; or F⁻, pH of about 7) partitioned into the interior aqueous phase within the microemulsion. Silicate is introduced by diffusion through the surfactant wall using non-polar silicate precursors such as tetraethylorthosilicate, Si(OEt)₄. This exemplary approach offers many advantages. The silicate precursor can be metered into the reaction vessel to control the rate of diffusion through the microemulsion wall. Particularly, hydrophobic SDA species may also be partitioned between the water and oil phases, thereby lending control over the SDA concentration in the aqueous reaction volume. Once nucleation begins, the particle size may be controlled by the volume of the emulsion reaction compartment. Particles can then only grow by emulsion-emulsion collisions and agglomeration and so preparation of zeotypes having narrow crystallite size distributions or aspect ratios is achieved.

More specifically, disclosed is the use of reverse microemulsions to control the morphology of crystals zeotypes, such as, but is not limited to, common aluminophosphate molecular sieve (AlPO₄-5) and a zeolite (Silicalite-1), during hydrothermal synthesis at elevated temperatures above 100° C., preferably at approximately 180° C. or more. By way of example, and not by way of limitation, for the AlPO₄-5 species, very long fibers are obtained in the microemulsion-based synthesis of the present invention, a morphology not observed previously for AlPO₄-5. These fibers have linear micropores parallel to the long axis of the fibers. The high aspect ratio of the fibers should allow their incorporation into materials with controlled crystal orientation. Similarly, the microemulsion approach could be used to control morphology of other complex materials.

To illustrate the subject method in more detail, two exemplary species will be utilized: AlPO₄-5 (an aluminophosphate or zeotype) and Silicalite-1 (a typical zeolite), but it is stressed that other equivalent species are considered to be within the scope of the present disclosure. Aluminophosphates are a widely studied class of microporous materials containing a variety of structural types (Wilson et al., J Am. Chem. Soc. 1982, 104:1146-1147). Aluminophosphate number five (AlPO₄-5) was selected to be synthesized because it is one of the most common molecular sieves and has application in catalysis, nonlinear optics, and membrane separations (Caro et al., Stud. Surf. Sci. Catal. 1997, 105:2171). The crystal structure has the IUPAC name AR and forms parallel linear pores with uniform diameters of 0.7 nm.

Generally, the subject synthesis scheme utilizes 1) a polar solute; 2) an metal source; 3) a silicon or phosphorous source; 4) an organic structure-directing agent (SDA); 5) a mineralizer; 6) at least one surfactant; and 7) a non-polar solvent.

The polar solute can be, but is not limited to, water, formamid, acetonitrile, dimethyl sulfoxide, or combinations thereof.

The metal source can be, but is not limited to, aluminum triisopropoxide, aluminum metal, aluminum sulfate, aluminum oxide, gallium sulfate, titanium tetrabutoxide, cobalt nitrate, or combinations thereof.

The silicon source can be, but is not limited to, tetraethylorthosilicate, silica, sodium silicate, or combinations thereof.

The phosphorous source can be, but is not limited to, phosphoric acid, phosphorous pentoxide, or combinations thereof.

The organic structure-directing agent (SDA) can be, but is not limited to, triethylamine, tetrapropylammonium bromide, tetrabutylammonium hydroxide, morpholine, N,N-diisopropylethylamine, di-n-propylamine, cyclohexlamine, quinuclidine, 18-crown-6 ether, hexamethonium bromide monohydrate, ethylenediamine, or combinations thereof.

The mineralizer can be, but is not limited to, hydrofluoric acid, sodium hydroxide, potassium hydroxide, ammonium fluoride, or combinations thereof.

The surfactant can be, but is not limited to, cetyl pyridinium chloride, sodium dodecyl sulfate (SDS), cetyl trimethylammonium bromide, and n-butanol, isopropyl alcohol, perfluorohexanol, lauric acid, poly(perfluoropropylene oxide) ammonium carboxylate, poly(propylene oxide)-block-poly(ethylene oxide), poly(dimethyl siloxane)-block-poly (ethylene oxide), poly(tetrafluoro ethylene)-block-poly(ethylene oxide) sorbitan monooleate, 3-[(3-Cholamidopropyl)dimethylammonio]-1-propanesulfonate, polyethylene glycol sorbitan monolaurate, or combinations thereof.

The non-polar solvent can be, but is not limited to, toluene, hexane, perfluorohexane, poly(perfluoropropylene oxide), carbon tetrachloride, iso-octane, compressed ethane, compressed carbon dioxide, or combinations thereof.

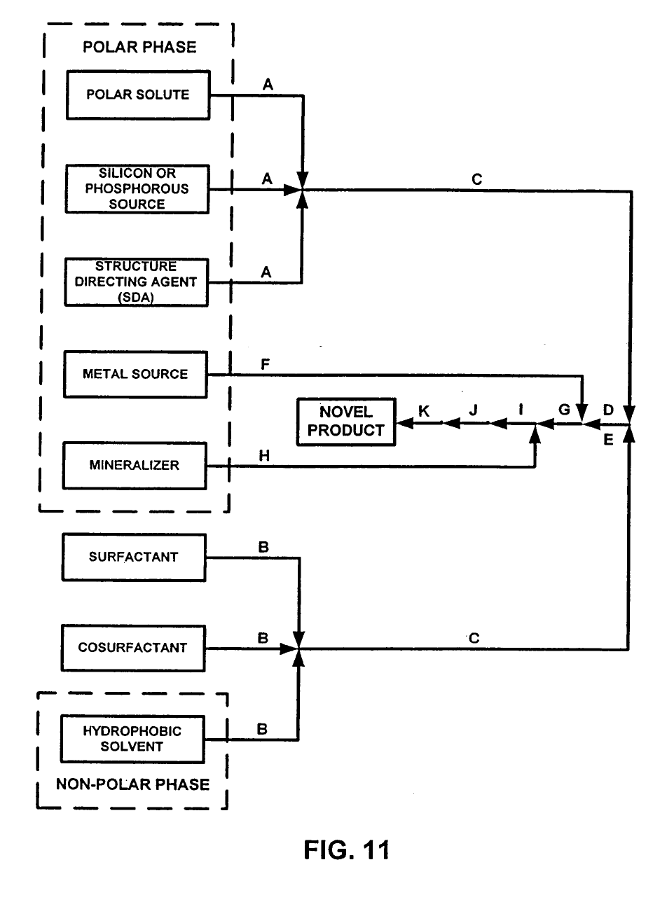

FIG. 11 summarizes a preferred synthesis method for producing general novel zeotypes. The polar phase materials comprising a polar solute, a silicon or phosphorous source, and a structure directing agent (SDA), which are mixed together in a suitable container (see “A” in FIG. 11). One or more surfactants/cosurfactants and the hydrophobic solvent are combined (see “B” in FIG. 11) and are added to the previously mixed three polar species and shaken for a short period of time to disperse the surfactants, preferably a minute or until a clear single phase reverse microemulsion is formed (see “C” in FIG. 11). The reverse microemulsion is then stirred for several hours, preferably overnight, at a suitable temperature, preferably about room temperature or the equivalent (see “D” in FIG. 11). The resultant reverse microemulsion is then cooled, preferably on ice for several minutes, preferably five to ten minutes (see “E” in FIG. 11). A metal source is then added and the

mixture is vigorously shaken for a short period of time, preferably one to three minutes (see “F” in FIG. 11). The mixture is then aged, preferably one to three hours, at a suitable temperature, preferably about room temperature or the equivalent (see “G” in FIG. 11). A mineralizer is then added (see “H” in FIG. 11). The resultant mixture is aged, preferably for one to three hours, at a suitable temperature, preferably about room temperature or the equivalent (see “I” in FIG. 11). After transfer to a suitable heating container, preferably a Teflon vessel, the mixture is heated to between about 100° C. to 220° C., preferably about 180° C., for a suitable time period, depending on the method of heating (conventional (conductive or convective), microwave, or the like) (see “J” in FIG. 11). For conventional (conductive or convective) heating the time is preferably five to seven hours without stirring. For microwave heating the time is preferably about one to three minutes to heat to the 100° C. to 220° C. range, more preferable about 180° C., and then maintains at that temperature for about an additional 15 to 20 minutes. The final novel product is then isolated, preferably by centrifugation followed by washing and then drying (see “K” in FIG. 11).

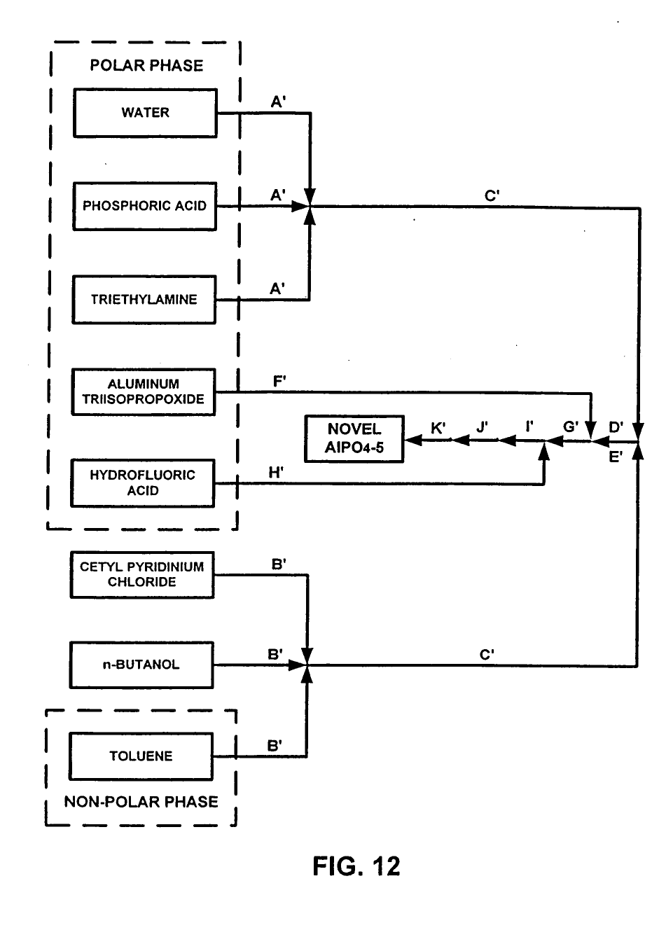

FIG. 12 summarizes the preferred synthesis method for novel AlPO₄-5 species and is also, applicable, with appropriate reactant substitutions and concentration alterations, for novel Silicalite-1 species. The letter designations from FIG. 12 have primes (′) to indicate equivalent steps to those depicted in FIG. 11 for the general zeolite procedure. The polar phase materials comprising water, phosphoric acid, and triethylamine (SDA) are mixed together in a suitable container (see “A′” in FIG. 12). Cetyl pyridinium chloride, n-butanol, and toluene are combined (see “8′” in FIG. 12) and are added to the previously mixed three polar species and shaken for a short period of time to disperse the surfactants, usually about a minute or until a clear single phase reverse microemulsion is formed (see “C′” in FIG. 12). The reverse microemulsion is stirred for several hours, preferably overnight, at a suitable temperature, preferably about room temperature or the equivalent (see “D′” in FIG. 12). The resultant reverse microemulsion is then cooled, preferably on ice for several minutes, preferably five to ten minutes (see “E′” in FIG. 12). Aluminum triisopropoxide is then added; and the mixture is vigorously shaken for a short period of time, preferably one to three minutes (see “F′” in FIG. 12). The mixture is then aged, preferably one to three hours, more preferably about two hours, at a suitable temperature, preferably about room temperature or the equivalent (see “G′” in FIG. 12). Hydrofluoric acid is then added (see “H′” in FIG. 12). The resultant mixture is aged, preferably for one to three hours, more preferably two hours, at a suitable temperature, preferably about room temperature or the equivalent (see “I′” in FIG. 12). After transfering to a suitable heating container, preferably a Teflon vessel, the mixture is heated, preferably to about 180° C., for a suitable time period, depending on the method of heating (conventional, microwave, or the like) (see “J′” in FIG. 12). For conventional heating, the time is preferably approximately five to seven hours without stirring. For microwave heating, the time is preferably about one to two minutes to heat to about 180° C., and then maintained at that temperature for about an additional 15 to 20 minutes, preferably about 17 minutes. The final novel product is then isolated, preferably by centrifugation followed by washing and then drying (see “K′” in FIG. 12).

The following examples are given to illustrate the present invention. It should be understood that the invention is not limited to the specific conditions or details described in these examples.

### EXAMPLE 1

### AlPO₄-5

With more specificity, an exemplary subject synthesis route for producing AlPO₄-5 began with a mixture of water, the aluminum source, the phosphorus source, the organic SDA, and appropriate mineralizer such as hydrofluoric acid, hydroxide, or equivalents. Phase behavior measurements on several surfactant systems were conducted to identify surfactants capable of solubilizing all of the components of the AlPO₄-5 synthesis mixture into a water-in-oil microemulsion. The mixture was treated as a pseudo-ternary system with oil, aqueous, and surfactant components. Toluene was chosen as the oil phase or non-polar solvent. Specifically, the aqueous phase was an AlPO₄-5 synthesis mixture consisting of water, aluminum triisopropoxide, phosphoric acid, hydrofluoric acid, and triethylamine in a molar ratio of 50:0.8:1.0:0.5:1.2, respectively (Caro et al., Microporous Mater. 1998, 22:560-661). The surfactant was a mixture of an ionic surfactant and n-butanol. The alcohol was added as a cosurfactant to improve microemulsion formation (Kahlweit et al., J. Phys. Chem. 1991, 95:5344-5352). Three ionic surfactants were investigated: sodium dodecyl sulfate (SDS), cetyl trimethylammonium bromide, and cetyl pyridinium chloride. Various concentrations of surfactant and aqueous phases in toluene were examined to determine regimes where an optically transparent, single-phase microemulsion formed at room temperature. It was determined that cetyl pyridinium chloride in a 2:1 weight ratio with n-butanol had the largest single-phase region, and was capable of solubilizing the greatest amount of the AlPO₄-5 synthesis mixture.

The mass fractions of components used for the hydrothermal synthesis were 0.219 cetyl pyridinium chloride, 0.109 n-butanol, 0.492 toluene, and 0.180 AlPO₄-5 synthesis mixture.

The microemulsion was formed by first mixing water, phosphoric acid, and triethylamine together at room temperature for five minutes. Then, cetyl pyridinium chloride, n-butanol, and toluene were added and the mixture was vigorously shaken for two minutes. At this point, a single-phase microemulsion formed. The microemulsion was aged overnight while stirring at room temperature. Aluminum triisopropoxide was then added and the mixture was shaken vigorously for one minute. Cooling the reaction on ice prior to addition of aluminum triisopropoxide was a desired additional step. If this additional cooling step was not performed, a larger amount of impurities appeared to have been incorporated into the product; and the obtained AlPO₄-5 crystals frequently did not have the desired fibrous shape. It was noted that occasionally a reaction conducted without this cooling step yielded the desired product. With cooling on ice, the results were more consistent.

After the addition of the aluminum source, the microemulsion was aged at room temperature for two hours. Hydrofluoric acid was then added and the microemulsion was aged for an additional two hours. At room temperature, this mixture formed a transparent single-phase microemulsion, unlike the traditional AlPO₄-5 synthesis mixture that appears milky white. Hydrothermal synthesis was conducted by heating the microemulsion to 180° C., with stirring, in a Teflon-lined autoclave for six hours. For a desired reproducible final product, turning off the stirring, once the reactor reached the desired reaction temperature, was preferred. If stirring was maintained throughout, the stirring sometimes caused the final product to be a different crystalline structure (a quartz-like structure called berlinite). This effect did not happen for all reaction conditions, but it consistently happened for some.

A control was also performed by using the same synthesis conditions, but without toluene, surfactant, and butanol. The solid product was collected by centrifugation, washed with ethanol, and dried overnight in a vacuum oven at 50° C.

The microemulsion-based synthesis resulted in the formation of long fibers approximately 200-300 nm in width and 15-30 microns in length (see FIG. 1A), with some groups of fibers aggregated into parallel bundles. The widths of the fibers were very uniform, while the lengths of the fibers vary greatly. The blunt ends observed on many fibers (see FIG. 1B), as opposed to sharp points, suggested that these fibers might have been broken during transfer to the scanning electron microscopy stage.

By comparison, the traditional synthesis resulted in the formation of irregular hexagonal columns approximately 4-8 microns in width and 5-12 microns in length (see FIG. 1C). The hexagonal columns appeared in a wide variety of sizes. The surfaces of the columns were rough, indicating that they were likely composed of multiply twinned crystals.

The powder X-ray diffraction pattern for the material synthesized through the microemulsion-based synthesis was consistent with the AFI structure, and appeared similar to the AlPO₄-5 diffraction patterns in the literature (Treacy et al., Collection of Simulated XRD Powder Diffraction Patterns for Zeolites, Elsevier, London, 1996). The one notable difference was the greatly reduced intensity of the (002) peak located at a Bragg angle 2Θ of 21.3°. The loss of intensity of the (002) peak indicated that the fibers were preferentially oriented horizontally, which was consistent with the observed orientation in FIG. 1A. From the preferred orientation of the fibers, it was concluded that the linear micropores was parallel to the long axis of the fibers.

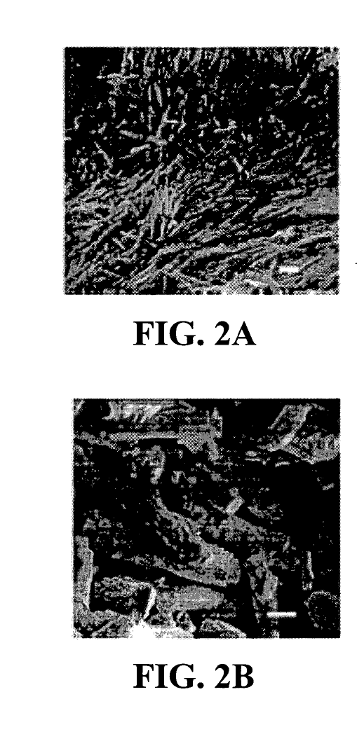

Microwave heating was explored as an alternative route for the synthesis of AlPO₄-5 from reactants enclosed in water-in-oil microemulsion droplets. Microwave heating often reduced the crystallization time and/or temperature required for hydrothermal synthesis of zeolites and molecular sieves, including AlPO₄-5 (Gimuset al., Zeolites1995, 15:33-39; and Zhao et al., in Progress in Zeolite and Microporous Materials (Eds.: H. Chon, S. K. Ihm, Y. S. Uh), Elsevier, London, 1997, pp. 181-187). Microemulsions were prepared by using the same procedure described above and then heated in a Teflon-lined vessel to 180° C. for 17 minutes in a commercial microwave. FIG. 2A showed the scanning electron micrograph of the product formed within the microemulsion after microwave heating. As with the synthesis in the autoclave, a fibrous product was produced. However, the particle size was much smaller, with widths of approximately 150 nm and lengths of up to 2-3 microns. The smaller fibers also displayed some tendency to aggregate into parallel bundles. For comparison, FIG. 2B showed the product formed from heating the traditional synthesis mixture in the microwave. The product appeared as multiply twinned crystals up to 50 microns in length and 10-15 microns in diameter, and was similar to the barrel-like morphology described by Wilson in the original synthesis of AlPO₄-5 (Wilson et al. in Intrazeollte Chemistry (Eds.: G. D. Stucky and F. G. Dwyer), American Chemical Society, Washington, D.C., 1983, pp. 79-106).

The powder X-ray diffraction patterns for the products from both the traditional synthesis and the microemulsion synthesis confirmed the AFI crystal structure. There was a slight reduction in the intensity of the (002) peak located at a Bragg angle 2Θ of 21.3° for both products, but not as much as observed for the longer fibers synthesized in the autoclave. Apparently, the smaller aspect ratio of the fibers produced in the microwave (10 compared to 100 for the fibers produced in the autoclave) reduced the preferred horizontal orientation.

General Hydrothermal Synthesis Conditions: Autoclave synthesis was conducted in a Teflon-lined pressure vessel (Parr, model 4744) wrapped in heating tape and controlled to a temperature of 180° C. for six hours. The reactor contents were stirred continuously using a magnetically coupled Teflon stir bar. Microwave synthesis was conducted in Teflon acid digestion vessels in a CEM MDS-2000 oven. The vessels were heated to 180° C. for 17 minutes without stirring.

General Powder X-ray Diffraction Conditions: Spectra were collected by using a Scintag XDS2000 diffractometer using an accelerating voltage of 45 kV and intensity of 40 mA. The diffraction pattern was collected from an angle 2Θ of 5 to 50°, using a step size of 0.02° and a collection time at each step of three seconds. Scanning electron micrographs were obtained by using a JEOL 6300FX high-resolution scanning electron microscope operating at an accelerating voltage of 1.0 kV.

### EXAMPLE 2

### Detailed Phase Diagram and Crystal Size/Shape Studies for AlPO₄-5

As noted above in Example 1, AlPO₄-5 was synthesized by hydrothermal synthesis in a water-in-oil microemulsion and had a fibrous morphology. The surfactant (cetyl pyridinium chloride) with cosurfactant (butanol) solubilized the standard aqueous AlPO₄-5 synthesis gel into a single phase microemulsion in toluene that is thermodynamically stable at room temperature. Several pseudo-ternary phase diagrams were measured to map the single-phase microemulsion region at room temperature and used as a guide for hydrothermal synthesis. By changing the composition of microemulsions, the crystal size and shape could be varied. The AlPO₄-5 crystal morphology changed from individual fibers to “fan-like” aggregates of fibers as the ratio of aqueous gel to surfactant was increased. As the ratio of toluene to aqueous gel increased, the formation of the dense phase aluminum phosphate berlinite was favored. Because the organic structure directing agent was not only soluble in aqueous phase but in the toluene phase, the concentration of the structure directing agent in the aqueous phase decreased with increasing amount of toluene; and the dense phase aluminum phosphate became the favored product. It was determined that double the standard amount of triethylamine was necessary for synthesis of high purity of AlPO₄-5 in the microemulsion.

Similar trends in crystal morphology were observed using microwave synthesis and conventional synthesis. The crystal size was typically smaller for microwave synthesis; and there was lower dense phase aluminum phosphate formation. Microwave energy offers faster crystallization time, 17 minutes versus approximately six hours for conventional synthesis. The microwave heating of water-in-oil microemulsions also offered the unique advantage of selective heating of the microemulsion droplets. Because many oils are transparent to microwaves, the aqueous droplets were rapidly and selectively heated within the oil.

The mechanism of the modification of crystal morphology was not simple templating by confinement within microemulsion droplets. The microemulsion influenced crystal morphology in the very early stages of nucleation and growth, possibly by influencing the amorphous precursor particles that form at room temperature and act as nucleation sites. The final crystal size was larger than the microemulsion droplets, so continued growth must occurred through solution transport outside of the microemulsion. The novel fibrous AlPO₄-5 morphology may allow oriented deposition onto substrates for formation of membranes or optical devices.

Several pseudo-temary phase diagrams were constructed to map the single-phase microemulsion region. The phase diagrams were used as a guide for hydrothermal synthesis at various microemulsion compositions. Crystallization of AlPO₄-5 was achieved at 180° C. either by conventional heating of the microemulsion for six hours or microwave heating for 17 minutes. The AlPO₄-5 crystal morphology changed from individual fibers to “fan-like” fiber aggregates as the ratio of AlPO₄-5 gel to surfactant increased. As the ratio of toluene to surfactant increased, nonporous berlinite became the favored product due to partitioning of the structure directing agent into toluene. Microwave heating produced smaller fibers and a less dense phase aluminum phosphate than conventional heating. The highly anisotropic AlPO₄-5 fibers may possibly allow easier control of crystal orientation when forming thin films for applications in membranes and optics. The microemulsion approach presented is applicable to hydrothermal synthesis of a variety of zeolites and molecular sieves to potentially control crystal morphology.

Experimental

Materials: Phosphoric acid (85%), triethylamine (99.5%), butanol (99.4%), toluene (99.5%), hydrofluoric acid (48%), cetyl pyridinium chloride (CPC, 98%) and aluminum triisopropoxide (99.99°) were purchased from Aldrich (St. Louis, Mo.) and used as received. Because of its sensitivity to moisture, aluminum triisopropoxide was stored in a desiccator.

Determination of Phase Diagrams: The measurement of the single phase region of microemulsion formation was described previously (Yates et al., Angew. Chem. Int. Ed. 2002, 41:476-478). The molar ratio of the components in the aqueous phase was kept constant and based on a synthesis gel composition for AlPO₄-5 from the literature (Robson, Microporous Mesoporous Mater. 1998, 22:495-670). For standard condition, the aqueous mixture is composed of water, aluminum triisoproxide, phosphoric acid, triethylamine, and hydrofluoric acid in a molar ratio of 50:0.8:1.0:0.6:0.5, respectively. The phase diagram was also investigated with double the molar ratio of triethylamine (1.2 moles per mole phosphoric acid). First, the aqueous AlPO₄-5 synthesis gel was formed and stirred at room temperature for approximately four hours. In a second vial, CPC, butanol, and toluene were added. The AlPO₄-5 synthesis mixture was added in increments to the second vial. After each addition of the aqueous mixture, the vial was stirred for a few minutes before visual observation. As the aqueous mixture was added, there was a sharp transition from a turbid mixture to an optically transparent single phase. Further, addition of the aqueous mixture eventually led to the return of a turbid multiphase mixture. The single-phase region can be mapped on a ternary phase diagram by repeating the process with different toluene/surfactant weight ratios. The phase diagram was used as a guide in selecting different compositions within the optically transparent single phase region for hydrothermal synthesis.

Hydrothermal Synthesis: De-ionized water, phosphoric acid, and triethylamine were first mixed together. It was preferred to mix triethylamine and phosphoric acid together first to allow the acid-base reaction and to minimize the solubility of triethylamine in the oil phase by formation of a salt with phosphoric acid. Then, cetyl pyridinium chloride, butanol, and toluene were added and shaken for one minute to disperse the surfactants. At this point, a clear single phase microemulsion had formed. The microemulsion was stirred overnight at room temperature. Then, the microemulsion was put on ice for 5-10 min. prior to adding aluminum triisopropoxide to obtain better crystallization (Jahn et al., Eur. Patent No. 0 406 872 A2, 1990). Aluminum triisopropoxide was then added and the mixture was shaken vigorously for 2 min., then aged at room temperature for two hours. Hydrofluoric acid was then added; and the microemulsion was aged for another two hours at room temperature. The optically transparent, single-phase microemulsion was then transferred to a Teflon vessel for hydrothermal synthesis.

For control experiments without the microemulsion, all aqueous components, except aluminum triisopropoxide and hydrofluoric acid, were mixed at room temperature. The mixture was then placed on ice for 5-10 min. prior to the addition of aluminum triisopropoxide. After adding aluminum triisopropoxide, the mixture was shaken for 2 min. and stirred for two hours at room temperature. Hydrofluoric acid was then added; and the mixture was aged an additional 2 hr. before hydrothermal synthesis.

Conventional heating: The Teflon-lined vessel (45 ml, model 4744, Parr Instrument Company) was wrapped in heating tape then heated to 180° C. and kept at this temperature for 6 hr. without stirring (Robson, Microporous Mesoporous Mater. 1998, 22:495-670).

Microwave heating: The microemulsion was heated in a microwave oven (Milestone Ethos Plus, with six 100 mL Teflon vessels) to 180° C. over 2 min. and kept at 180° C. for 17 min. without stirring. The maximum power output of the microwave was adjusted to 500 Watts.

Product collection: For both heating methods, the product was collected by centrifugation after the temperature of the liquid decreased to room temperature. The liquid was then transferred to a 28 mL centrifuge tube and centrifuged at the speed of 14,500 rpm for 30 min. The collected solid was then washed with ethanol twice with the same centrifugation conditions. Finally, the product was dried overnight in a vacuum oven at 50° C.

Characterization: The morphology of the products was examined with scanning electron microscopy (LEO 982 FE-SEM) after coating with 800 to 1000 angstroms of metal (Au 60%, Pd 40%). The crystal structure was determined by powder X-ray diffraction (Philips PW3020) with an integration time of two hours and a step size of 0.02 degree/3 sec.

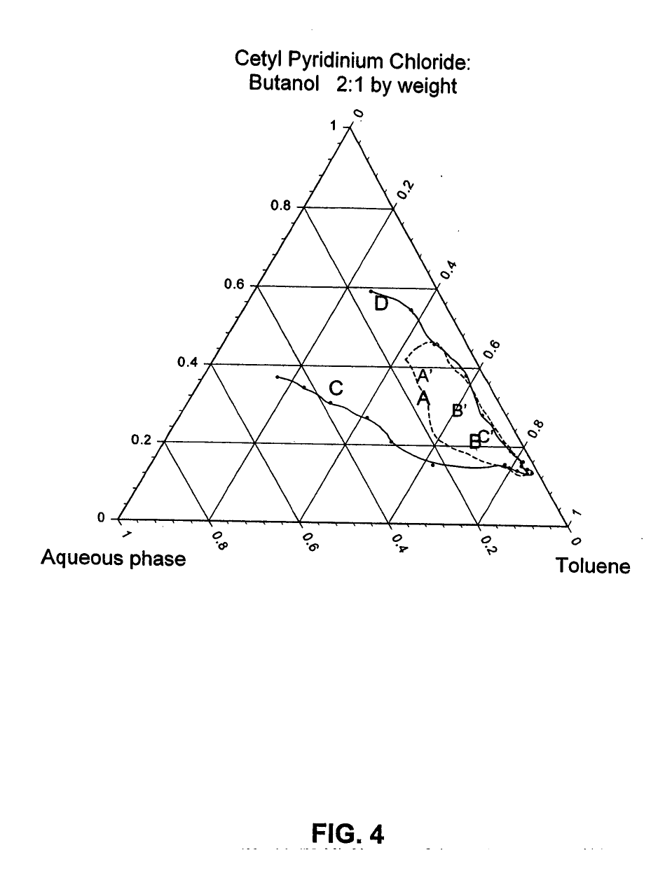

Results: FIG. 4 shows the phase diagram for the surfactant CPC and cosurfactant butanol in the ratio of 2:1 by weight. The area between the lines on the diagram indicated the formation of the single-phase microemulsion. Two single-phase regions were evident corresponding to two different molar ratios of triethylamine structures directing agent in aqueous phase. Phase behavior was determined using the standard molar ratio from the literature of 0.6 moles triethylamine per mole phosphoric acid and double the standard ratio (1.2 moles triethylamine per mole phosphoric acid). The larger single-phase region (enclosed with black line) corresponded to double the standard amount of structure directing agent. The differences in the two phase diagrams are due to pH changes in the aqueous phase that can strongly affect phase behavior. There was an acid-base equilibrium between triethylamine and phosphoric acid in the synthesis gel. The pH will thus be strongly dependent on the ratio of triethylamine to phosphoric acid. The ammonium salt formed when triethylamine reacts with phosphoric acid is only soluble in the aqueous phase. However, the unprotonated triethylamine is soluble in toluene. Therefore, there is also likely an equilibrium partitioning of triethylamine between the oil and aqueous phases that can affect pH as well as change the actual triethylamine concentration in the aqueous phase. Triethylamine and phosphoric acid were mixed together to ensure salt formation prior to the addition of toluene to minimize the solubilization of triethylamine in the oil phase. A-D on the phase diagram represented compositions chosen for hydrothermal synthesis within the single-phase region with twice the standard molar ratio of triethylamine. Similarly, A′-C′ were the compositions chosen for hydrothermal synthesis within the single-phase region with the standard synthesis gel. The points were selected to sample a wide range of single-phase microemulsion compositions.

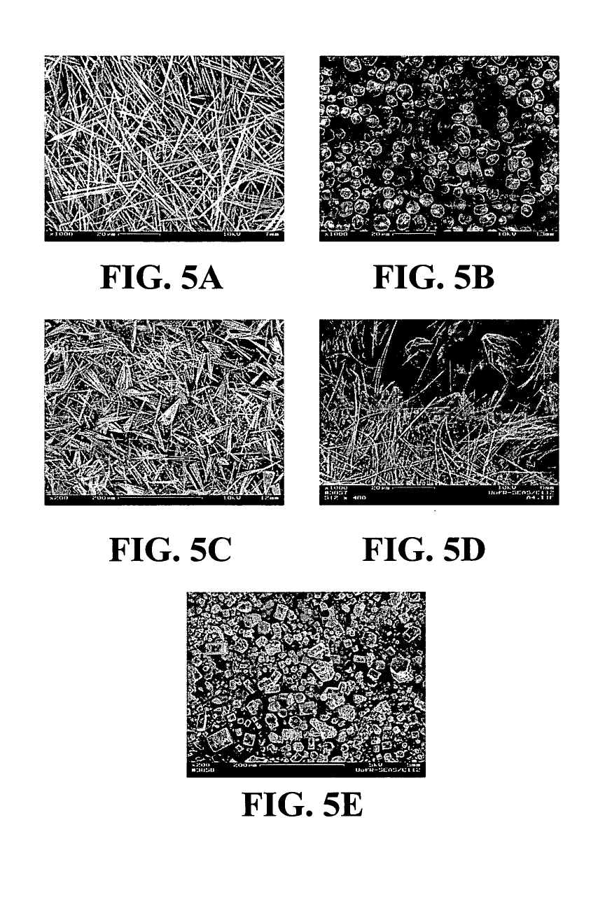

The crystal morphologies obtained by hydrothermal synthesis from the microemulsions with conventional heating were shown in FIG. 5. FIGS. 5A-5D corresponded to compositions A-D, respectively, from FIG. 4. FIG. 5E was the control experiment using traditional hydrothermal synthesis without the microemulsion, which showed hexagonal columns with wide size distribution in the range from 5-40 μm in width and 5-55 μm in length. As seen in an earlier study (Yates et al., Angew. Chem. Int. Ed. 2002, 41:476-478), point A (49 wt % toluene, 33 wt % CPC/butanol, and 18 wt % synthesis gel) had crystals in the shape of long fibers (FIG. 5A), which possesed lengths in the range from 20-70 μmand widths from 250-700 nm. The products obtained for point B (70 wt % toluene, 20 wt % CPC/butanol) had spherical or football-like shapes with the sizes from 5-20 μm (FIG. 5B). Synthesis at point C (30 wt % toluene, 34 wt % CPC/butanol) also produced fibrous crystal morphology (FIG. 5C). The morphology of these particles was similar to those synthesized at point A (FIG. 5A) except that many of the fibers are aggregated together in a fan-like formation. The product obtained from point D (30 wt % toluene, 56 wt % CPC/butanol) was a mixture of fibers and football-shaped crystals. These fibers were thinner than those obtained at point A, and in some cases, appeard to bend.

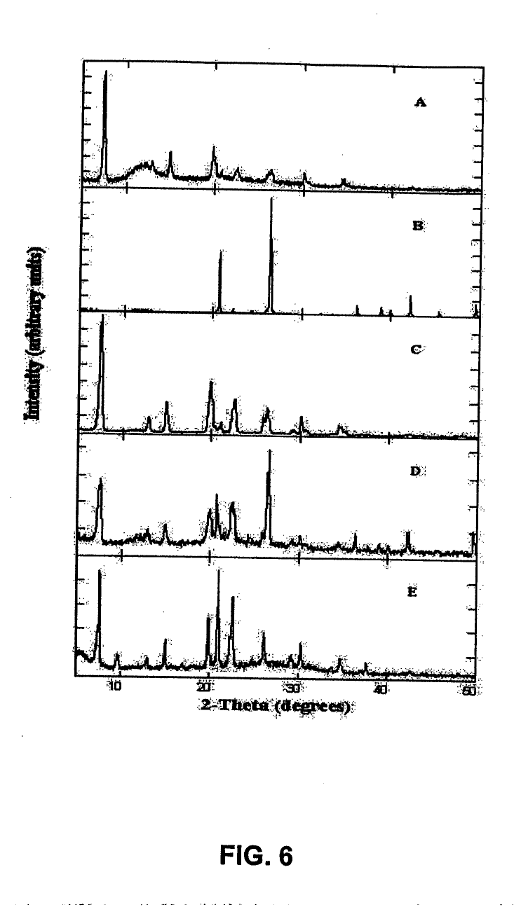

Powder X-ray diffraction was used to investigate the crystal structure of samples shown in FIGS. 5A-5E. The diffraction patterns were depicted in FIGS. 6A-6E, and corresponded to crystals shown in FIGS. 5A-5E, respectively. The patterns shown in FIGS. 6A and 6C were that of the AFI crystal structure of AlPO₄-5, and were consistent with the pattern of the control experiment shown in FIG. 6E. The diffraction pattern in FIG. 6B was that of berlinite, the aluminum phosphate isostructural analog of alpha quartz. FIG. 6D had features of both the AFI and berlinite patterns, and thus, indicates that the sample is a mixture of berlinite and AlPO₄-5. By comparison of FIGS. 5 and 6, it can be seen that the AlPO₄-5 crystals are fibrous, whereas the berlinite crystals are football-shaped or near spherical.

Berlinite was a dense phase material slightly more thermodynamically stable than AlPO₄-5 (Hu et al., Chem. Mater. 1995, 7:1816-1823). In fact, we had observed that the AlPO₄-5 fibers underwent structural transformation to berlinite during the synthesis. For the reaction conducted at the composition of point B in FIG. 4, the collected product was a mixture of berlinite and AlPO₄-5 fibers when the reaction time was reduced to two hours. The fraction of fibers observed gradually decreased as reaction time increased. At a reaction time of six hours, fibers were no longer observed and the product was pure berlinite (FIGS. 5B and 6B).

Because of the complex nucleation and growth mechanism of molecular sieves, the results were often influenced by many factors. For example, keeping the autoclave vessel agitated or static sometimes leads to different crystal structures in the synthesis of zeolite Beta (Caullet et al., Zeolites1992, 12:240-250). In the present investigation, it was observed that under some conditions stirring with a magnetically coupled stir bar can influence crystal quality, and in some cases, resulted in a different crystal structure. Stirring during the heat-up period had little effect as long as the reactor was maintained static after reaching 180° C. However, if the vessel was stirred at 1,100 rpm throughout the reaction, the product at the microemulsion composition of point A (FIG. 4) was transformed from nanoporous AlPO₄-5 to dense phase berlinite.

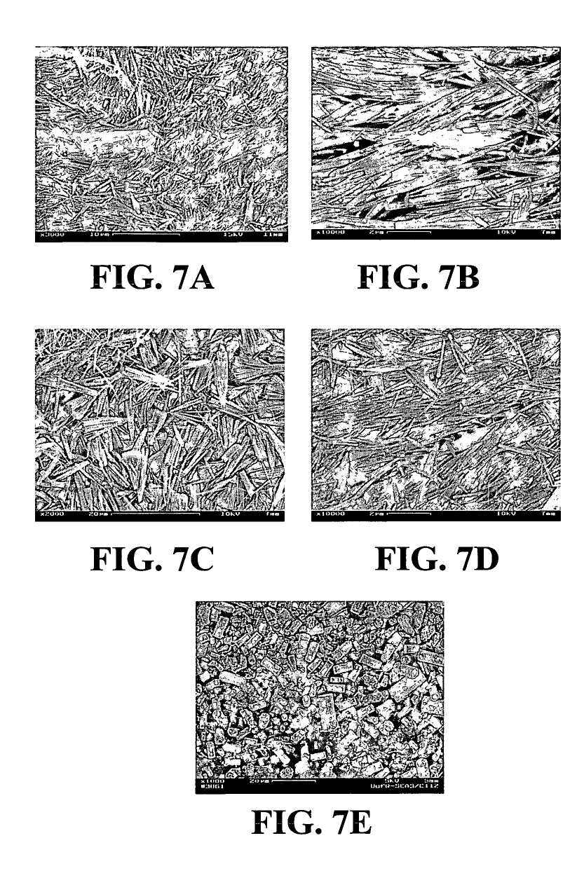

For the hydrothermal synthesis conducted in microwave oven, AlPO₄-5 fibers were obtained for all four compositions A-D as shown in FIGS. 7A-7D. Some fibers produced at point A with microwave heating revealed the same fan-like morphology as those produced at point C with conventional heating. By tuning the maximum power output and the time required to heat to 180° C. as described in the experimental section, the numbers of aggregated fibers could be suppressed to a low level. For point C, the fibers of fan-like shape could also be observed. For point B and point D, the resulting materials were also AlPO₄-5 fibers but had poor crystallization. There was amorphous material in the product, as determined by powder X-ray diffraction and scanning electron microscopy. The size of the fibers was around 2-4 μm in length and 150 nm in width for points A, B, and D. The fan-like shaped fibers had the largest particle size. The length of fibers is around 10 μm and up to 500 nm in width. FIG. 7E was the control experiment without the microemulsion. Unlike the fibers obtained for all compositions with microemulsion, the AlPO₄-5 crystals appeared in the shape of circular columns with the size up to 20 μm in length and 8 μm in width.

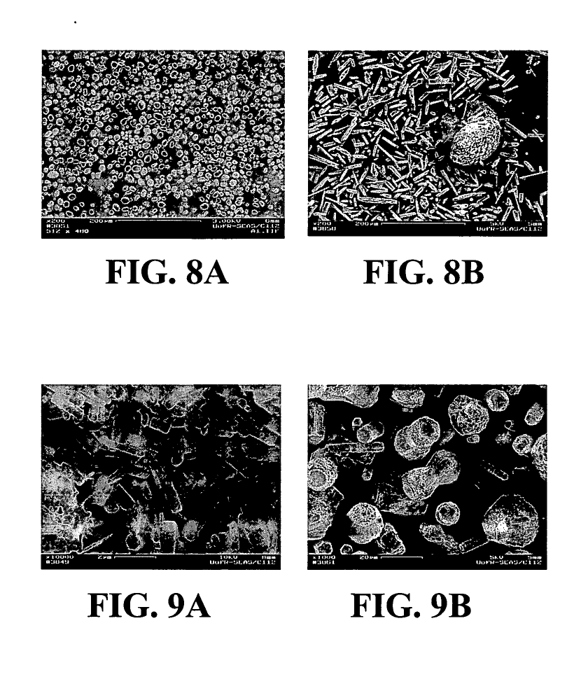

The single-phase microemulsion region became smaller by changing the molar ratio of triethylamine to the standard value of 0.6 moles per mole of phosphoric acid (dash-line in FIG. 4). Three points were chosen for the hydrothermal synthesis to represent the whole single-phase region. The compositions were point A′ (50 wt % toluene, 35 wt % CPC/butanol), point B′(60 wt % toluene, 30 wt % CPC/butanol), and point C′ (68 wt % toluene, 24 wt % CPC/butanol). All three reactions produced berlinite by conventional heating. FIG. 8A showed a selected picture for point C′. The control reaction without the microemulsion produced hexagonal AlPO₄-5 crystals 4-15 μm in width and 30-70 μm in length with some multiply twinned crystals (FIG. 8B).

By microwave heating, pure AlPO₄-5 crystals were produced for point A′ mostly in the shape of circular columns with a small amount of fibers (FIG. 9A). For compositions B′ and C′, the products also contained columns and fibers. However, the X-ray diffraction shows the products from compositions B′ and C′ contain an impurity of cristobalite. Cristobalite is a dense phase material with a slightly higher enthalpy of formation than berlinite (Hu et al., Chem. Mater. 1995, 7:1816-1823).

The control experiment produced multiply twinned crystals in the formation of “dumb-bell” and “half-dumb-bell” shapes (FIG. 9B). The twinned crystals also appeared as hexagonal columns in some cases. The size of the crystals was approximately 20 μm in length and 10 μm in diameter, which was very similar dimensions to the product obtained for the control experiment by microwave heating with double amount of triethylamine.

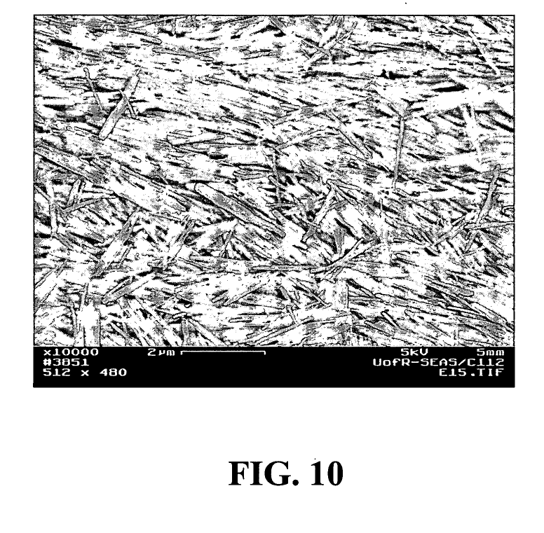

A very small single-phase region could be formed when the weight ratio of CPC to butanol was changed to 3:1 with double standard molar ratio of triethylamine. A reaction from this microemulsion (48 wt % toluene, 40 wt % CPC/butanol) demonstrated a poor crystallization for conventional heating. There were fibers with a large amount of amorphous material and some crystals of berlinite and cristobalite. However, pure AlPO₄-5 was obtained by microwave heating, revealing small fibers with lengths from 1-2 μm and widths from 30-55 nm (FIG. 10).

In conclusion, the formation of microporous materials during hydrothermal synthesis is a complex process of self-assembly coupled with several simultaneous chemical reactions. The mechanism of nucleation and growth is poorly understood, but a recent study has shown that Zeolite A crystals are nucleated within amorphous precursor particles (Mintova et al., Science1999, 283:958-960). The size and shape of the final crystal is the same as the amorphous precursor particle, but further crystal growth is attained upon heating through Ostwald-ripening type mechanism. It has been proposed that AlPO₄-5 crystallization occurs through a similar route where an amorphous precursor consisting of a self-assembled array of inorganic and organic (structure-directing agent, SDA) material converts to AlPO₄-5 crystals upon heating. (Gimus et al., Zeolites1995, 15:33-39). Concentrated water-in-oil microemulsions often form cylindrical aggregates, and these aggregates have been used as templates to form rod-shaped materials (Tanod et al., Langmuir1997, 13:639-646). We believe that a similar templating mechanism may be operative in the molecular sieve synthesis. Such a mechanism would involve dual templating: the structure-directing agent templates the micropores within the crystal, while the surfactant aggregate surrounding the amorphous precursor templates the crystal size and shape. While we believe the surfactant aggregates template crystal nucleation, the final crystal size is much larger than typical surfactant aggregates, so crystal growth must continue outside the microemulsion droplets. Again, the microporous AlPO₄-5 fibers synthesized in the microemulsion are applicable in optic, sensor, or membrane technologies, where the high aspect ratio of the fibers allows deposition onto substrates with controlled crystal orientation.

### EXAMPLE 3

### Silicalite-1

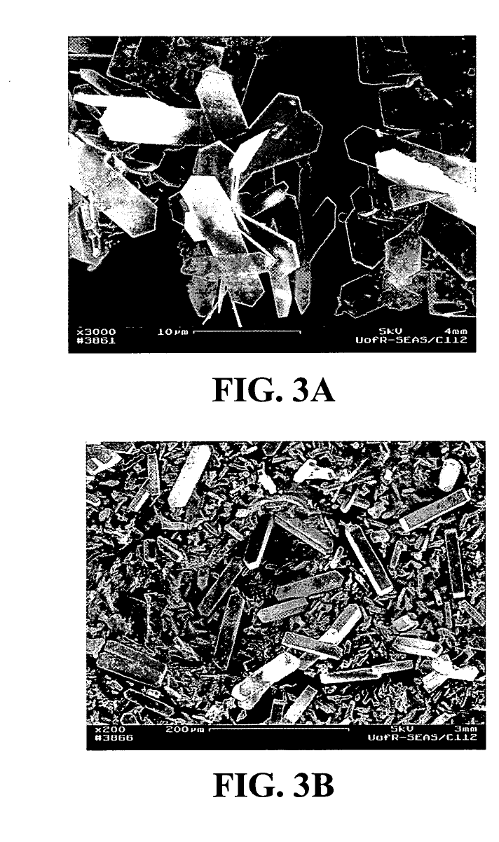

A novel form of Silicalite-1 was synthesized by the present method. The aqueous phase comprised silica, ammonium fluoride, tetrapropylammonium bromide, and water in a ratio of 1:1:0.4:40, respectively. The non-aqueous phase comprised cetyl pyridinium chloride, n-butanol, and toluene. The novel crystals shown in FIG. 3A were synthesized via the present reverse microemulsion procedure and heated for six days at 180° C. by conventional heating. The control crystals shown in FIG. 3B did not contain the non-aqueous phase, but were heated for six days at 180° C. using conventional heating. The present reverse microemulsion process produced crystals that shaped like thin plates and smaller (FIG. 3A) than the “coffin-shaped” crystals found in the conventional preparation (FIG. 3B).

Although the description above contains many details, these should not be construed as limiting the scope of the invention but as merely providing illustrations of some of the presently preferred embodiments of this invention. Therefore, it is appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, is but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. A method for making a microporous crystal comprising the steps of:
a) mixing a polar solute, a silicon or phosphorus source, and a structure directing agent (SDA) to produce a first mixture;
b) mixing at least one surfactant and a non-polar solvent to produce a second mixture;
c) combining said first and said second mixtures to produce a reverse microemulsion;
d) adding a metal source to said reverse microemulsion to produce a third mixture; and
e) adding a mineralizer to said third mixture to produce a fourth mixture.

2. The method of claim 1, wherein the microporous crystal is AlPO₄-5 or Silicalite-1.

3. The method of claim 1, wherein the SDA is selected from the group consisting of triethylamine, tetrapropylammonium bromide, tetrabutylammonium hydroxide, morpholine, N,N-diisopropylethylamine, di-n-propylamine, cyclohexlamine, quinuclidine, 18-crown-6 ether, hexamethonium bromide monohydrate, ethylenediamine, and combinations thereof.

4. The method of claim 1, wherein the polar solute is selected form the group consisting of water, formamid, acetonitrile, dimethyl sulfoxide, and combinations thereof.

5. The method of claim 1, wherein the silicon source is selected from the group consisting of tetraethylorthosilicate, silica, sodium silicate, and combinations thereof.

6. The method of claim 1, wherein the phosphorous source is selected from the group consisting of phosphoric acid, phosphorous pentoxide, and combinations thereof.

7. The method of claim 1, wherein the surfactant is selected from the group consisting of cetyl pyridinium chloride, SDS, n-butanol, isopropyl alcohol, perfluorohexanol, lauric acid, poly(perfluoropropylene oxide) ammonium carboxylate, poly(propylene oxide)-block-poly (ethylene oxide), poly(dimethyl siloxane)-block-poly(ethylene oxide), poly(tetrafluoro ethylene)-block-poly(ethylene oxide) sorbitan monooleate, 3-[(3-Cholamidopropyl)dimethylammonio]-1-propanesulfonate, polyethylene glycol sorbitan monolaurate, and combinations thereof.

8. The method of claim 1, wherein the non-polar solvent is selected from the group consisting of toluene, hexane, perfluorohexane, poly(perfluoropropylene oxide), carbon tetrachloride, iso-octane, compressed ethane, compressed carbon dioxide, and combinations thereof.

9. The method of claim 1, wherein the metal source is selected from the group consisting of aluminum triisopropoxide, aluminum metal, aluminum sulfate, aluminum oxide, gallium sulfate, titanium tetrabutoxide, cobalt nitrate, and combinations thereof.

10. The method of claim 1, wherein the mineralizer is selected from the group consisting of hydrofluoric acid, sodium hydroxide, ammonium fluoride, potassium hydroxide, and combinations thereof.

11. The method of claim 1, further comprising the step of
f) heating said fourth mixture.

12. The method of claim 11 wherein step f) takes place at about 100-220° C.

13. The method of claim 11, wherein step f) takes place at about 180° C.

13. The method of claim 11, further comprising the step of
g) recovering the microporous crystal.

14. The method of claim 13, wherein step g) is accomplished by centrifugation.

15. The method of claim 1, wherein step c) is accomplished by shaking until a clear single phase reverse microemulsion is formed, followed by stirring.

16. The method of claim 15, wherein the stirring occurs for several hours at about room temperature.

17. The method of claim 1, wherein the reverse microemulsion is cooled prior to step d).

18. The method of claim 17, wherein the cooling occurs on ice for about 5-10 minutes.

19. The method of claim 1, wherein said third mixture is aged immediately prior to step e).

20. The method of claim 19, wherein the aging takes place at about room temperature for about 1-3 hours.

21. The method of claim 11, wherein said fourth mixture is aged immediately prior to step f).

22. The method of claim 21, wherein the aging takes place at about room temperature for about 1-3 hours.

23. The method of claim 11, wherein step f) is accomplished by conventional or microwave heating.

24. The method of claim 23, wherein conventional heating takes about 5-7 hours.

25. The method of claim 24, wherein the heating takes place without stirring.

26. The method of claim 23, wherein microwave heating comprises heating said fourth mixture to a temperature of about 100-220° C. in about 1-3 minutes; and holding said fourth mixture at the temperature for about 15-20 minutes.

27. The method of claim 1, wherein the microporous crytal is a zeotype crystalline species.

28. A microporous crystal comprising elongated fibers having micropores parallel to the long axis of the fibers.

29. The microporous crystal of claim 28, wherein the fibers aggregate into parallel bundles.

30. The microporous crystal of claim 28, wherein the fibers have dimensions of about 200-300 nm in width and about 15-30 microns in length.

31. The microporous crystal of claim 28, wherein the fibers are a zeotype species.

32. The microporous crystal of claim 28, wherein the crystals are AlPO₄-5 or Silicalite-1.

33. The microporous crystal of claim 28, wherein powder X-ray diffraction of the fibers shows greatly reduced intensity of the peak located at a Bragg angle 2Θ of 21.30°.

34. A microporous crystal made by the method of claim 1.
